(19) United States
(12) Patent Application Publication
(10) Pub. No.: US 2007/0045641 A1
(43) Pub. Date: Mar. 1, 2007

(54) Light source with UV LED and UV reflector

(76) Inventors: Janet Bee Yin Chua, Perak (MY); Rene P. Helbing, Palo Alto, CA (US); Thye Linn Mok, Penang (MY); Kee Yean Ng, Penang (MY); Gim Eng Chew, Penang (MY); Wooi Kin Goon, Penang (MY); Yue Hoong Lau, Penang (MY)

Correspondence Address: AVAGO TECHNOLOGIES, LTD., P.O. BOX 1920, DENVER, CO, 80201-1920, US

(21) Appl. No.: 11/210,714

(22) Filed: Aug. 23, 2005

(51) Int. Cl. H01L 29/22; H01L 33/00

(52) U.S. Cl. 257/98; 313/110

(57) ABSTRACT

A lighting source capable of producing white light using a semiconductor radiation source. The semiconductor radiation source may be an ultraviolet (“UV”) light emitting diode (“LED”) device that emits light at a short wavelength, e.g., near-violet or ultraviolet light. A thin film of phosphor may be deposited or coated on the surface of the UV LED or positioned directly above the UV LED. The lighting source may also include an UV reflector radiationally coupled to the thin phosphor layer that allows visible white light emitted from the thin phosphor to pass through and reflects shorter wavelength light back to the thin phosphor layer.

### BACKGROUND OF THE INVENTION

Light emitting diodes (“LEDs”) are, in general, miniature semiconductor devices that employ a form of electroluminescence resulting from the electronic excitation of a semiconductor material to produce visible light. Initially, the use of these devices was limited mainly to display functions on electronic appliances and the colors emitted were red and green. As the technology has improved, LEDs have become more powerful and available in a wide spectrum of colors.

With the fabrication of the first blue LED in the early 1990's, emitting light at the opposite end of the visible light spectrum from red, the possibility of creating virtually any color of light was opened up. With the capability to produce the primary colors, red, green, and blue (i.e., the RGB color model), with LED devices, there is now also the capability to produce virtually any color of light, including white light. With the capability of producing white light, there is now the possibility of using LEDs for illumination in place of incandescent and fluorescent lamps. White-light illumination is also very useful in certain medical applications, e.g., medical instruments for surgery, endoscopy, and color-picture evaluation. The advantages of using LEDs for illumination is that they are far more efficient than conventional lighting, are rugged and very compact, and can last much longer than incandescent or fluorescent light bulbs or lamps.

White light can be made in different ways: by mixing reds, greens, and blues; by using an ultraviolet (“UV”) LED to stimulate a white phosphor; or by using a blue-emitting diode that excites a yellow-emitting phosphor embedded in an epoxy dome, where the combination of blue and yellow makes a white-emitting LED. Also, by combining a white phosphor LED with multiple amber LEDs, a range of different whites can be created.

The combination of red, blue, and green diode chips in one discrete package, or in a lamp assembly housing a cluster of diodes, is the preferred method in applications requiring a full spectrum of colors from a single point source. This method, however, is not as useful in generating white light of the desired tone because of variations in the tone and luminance of the light emitted by the three light emitting components and other problems inherent in mixing the light emitted by these components.

Most white-light diodes employ a semiconductor chip emitting at a short wavelength (blue, violet or ultraviolet) and a wavelength converter, which absorbs light from the diode that undergoes secondary emission at a longer wavelength. Such diodes, therefore, emit light of two or more wavelengths, which, when combined, appear as white. The quality and spectral characteristics of the combined emission vary with the different design variations that are possible. The most common wavelength converter materials are termed phosphors, which, generally, are any substances that exhibit luminescence when they absorb energy from another radiation source. The phosphors typically utilized are composed of an inorganic host substance containing an optically active dopant. Yttrium aluminum garnet (“YAG”) is a common host material, and for diode applications, it is usually doped with one of the rare-earth elements or a rare-earth compound. Cerium is a common dopant element in YAG phosphors designed for white light emitting diodes.

Most “white” LEDs in production today use a 450 nm-470 nm blue gallium nitride (“GaN”) LED covered by a yellowish phosphor coating usually made of cerium doped yttrium aluminium garnet (“YAG:Ce”) crystals that have been powdered and bound in a type of viscous adhesive. The LED chip emits blue light, part of which is converted to yellow by the YAG:Ce. The single crystal form of YAG:Ce is actually considered a scintillator rather than a phosphor. Since yellow light stimulates the red and green receptors of the human eye, the resulting mix of blue and yellow light gives the appearance of white light.

The first commercially available white-light-emitting device (fabricated and distributed by the Nichia Corporation) is based on a blue-light-emitting gallium-indium-nitride (“GaInN”) semiconductor device surrounded by a yellow phosphor. An example of such a device is disclosed in U.S. Pat. No. 5,998,925, titled “Light Emitting Device Having a Nitride Compound Semiconductor and a Phosphor Containing a Garnet Fluorescent Material,” to Shimizu et al.

FIG. 1 illustrates the cross-sectional structure of such a typical light emitting device. The LED device 100 is provided with a mount lead 102 and an inner lead 104. The mount lead 102 also comprises a reflector cup 106, in which a blue-emitting diode 108 is affixed. The reflector cup 106 is filled with an epoxy resin 114 in which is suspended a powdered phosphor. An n electrode and a p electrode of the light emitting component 108 are connected to the mount lead 102 and the inner lead by bonding wires 110 and 1 12, respectively.

The phosphor may be Ce-doped YAG, produced in powder form and suspended in the epoxy resin 114 used to encapsulate the die. The phosphor-epoxy mixture fills the reflector cup 106 that supports the die on the mount lead 102, and a portion of the blue emission from the chip is absorbed by the phosphor and re-emitted at the longer phosphorescence wavelength. The combination of the yellow photo-excitation under blue illumination is ideal in that only one converter species is required. Complementary blue and yellow wavelengths combine through additive mixing to produce the desired white light. The resulting emission spectrum of the LED represents the combination of the phosphor emission, with the blue emission that passes through the phosphor coating unabsorbed.

White light diodes can generate emission by another mechanism, i.e., utilizing broad-spectrum phosphors that are optically excited by near-violet or ultraviolet radiation. In such devices, an ultraviolet-emitting diode is employed to transfer energy to the phosphor, and the entire visible emission is generated by the phosphor. An advantage of this method of producing white light is that it gives color performance superior to that of the blue-light-emitting LED because the UV LED does not contribute appreciably to the visible color produced by the device.

Phosphors that emit at a broad range of wavelengths, producing white light, are readily available as these are the same materials used in the manufacture of fluorescent tubes and cathode ray tubes. Although fluorescent tubes derive their UV emission from a gas discharge process, the phosphor emission stage producing white light output is the same as in UV-pumped white diodes. The phosphors have well known color characteristics and devices of this type have the advantage that they can be designed for applications requiring critical color rendering. A significant disadvantage of the UV-pumped diodes, however, is their lower luminous efficiency when compared to white diodes employing blue light for phosphor excitation. This results from the relatively high energy loss in the down-conversion of UV light to longer visible wavelengths.

Also, another drawback of using UV LEDs is the faster degradation of the packaging materials, i.e., the epoxy around the diode used to encapsulate the light emitting device, due to the high photon energy that can cause chemical-bond cracks, and a structural breakdown of the epoxy material. This results in luminance (“Lv”) degradation, that is, less light output, over time as the phosphor/epoxy material is subjected to the UV radiation from the UV LED. Moreover, the use of UV emissions also increases the risks of hazards to the human eye, which have to be compensated for.

Therefore, there is a need to reduce the effect of UV epoxy or material degradation within the UV LED, thereby improving the luminance efficiency and the longevity of the light source. Additionally, there is a need to prevent the leakage of UV emissions from the LED for reasons of safety to the human eye.

### SUMMARY

A light source that produces a white light using an ultraviolet (“UV”) light emitting diode (“LED”) device and a UV reflector is disclosed. The light source may include as its radiation source a UV LED that emits light at a short wavelength, e.g., near-violet or ultraviolet, and a thin film of phosphor deposited or coated on the surface of the UV LED. The light source may also include a UV reflector material positioned above the thin phosphor layer.

In an example of operation, the UV LED emits short wavelength light, which then strikes the thin phosphor layer. A portion of the short wavelength light is converted to white light by the phosphor layer, and another portion of the short wavelength light is transmitted through the phosphor layer. The portion of light that passes through the phosphor layer strikes a UV reflector, which allows visible light to pass through and reflects the UV light back to the phosphor layer. The phosphor layer converts the reflected UV light to white light, which is then re-emitted through the phosphor layer.

Other systems, methods and features of the invention will be or will become apparent to one with skill in the art upon examination of the following figures and detailed description. It is intended that all such additional systems, methods, features and advantages be included within this description, be within the scope of the invention, and be protected by the accompanying claims.

### BRIEF DESCRIPTION OF THE DRAWINGS

The invention can be better understood with reference to the following figures. The components in the figures are not necessarily to scale, emphasis instead being placed upon illustrating the principles of the invention. In the figures, like reference numerals designate corresponding parts throughout the different views.

FIG. 1 shows a schematic sectional view illustrating an example of an implementation of a known light source that includes an LED.

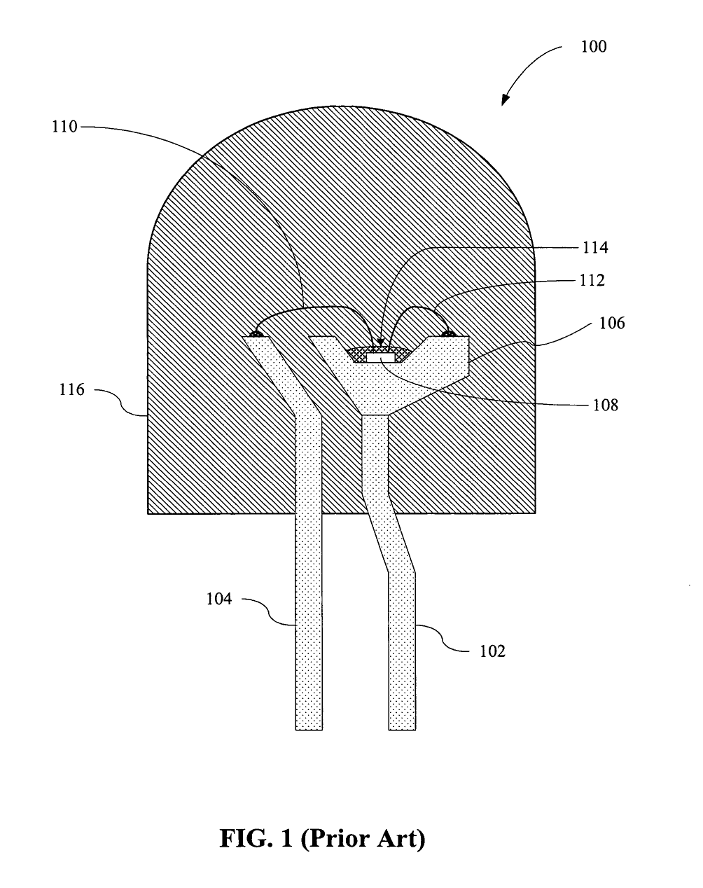

FIG. 2 shows a schematic sectional view illustrating an example of an implementation of a light source that includes a UV LED and a UV reflector.

FIG. 3 shows a schematic sectional view of the light source shown in FIG. 2 that illustrates the UV LED and the UV reflector in greater detail.

FIG. 4 shows a graphical representation of a plot of reflectivity versus light wavelength in nanometers (“nm”) for an example implementation of the UV reflector shown in FIGS. 2 and 3.

### DETAILED DESCRIPTION

In the following description of the preferred embodiment, reference is made to the accompanying drawings that form a part hereof, and which show, by way of illustration, a specific embodiment in which the invention may be practiced. Other embodiments may be utilized and structural changes may be made without departing from the scope of the present invention.

In general, the invention is a light source that may include a radiation source that may be an ultraviolet (“UV”) light-emitting diode (“LED”) that emits short wavelength light that may be near-violet or ultraviolet light on the visible and invisible light spectrum, i.e., light with a wavelength of about 400 nanometers (“nm”) or less. In general, the term “UV light” refers to light with wavelengths that are not capable of being seen by the human eye.

The light source may also include a thin phosphor layer or coating applied to the surface of the UV LED. Above the thin phosphor layer may be an UV reflector capable of reflecting the UV light emitted by the UV LED and allowing light of greater wavelengths to pass through the UV reflector. The reflected UV light may strike the thin phosphor layer again, thereby converting the reflected UV light to visible light, which will then pass through the UV reflector, producing a white light of a shade dependent on the phosphor material in the thin phosphor layer.

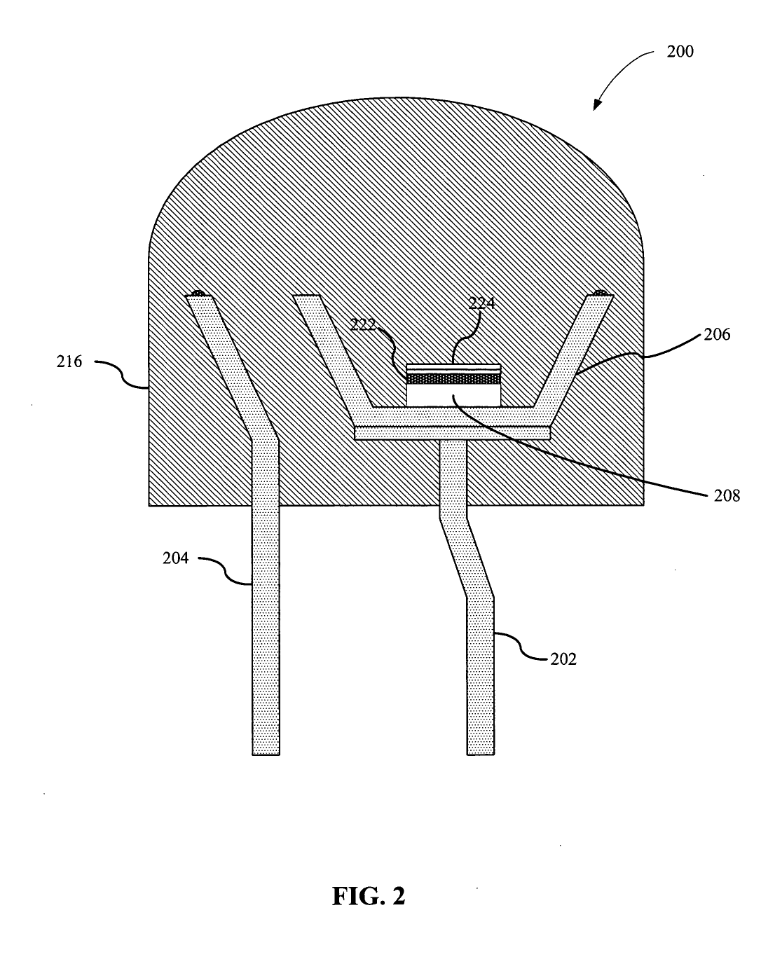

FIG. 2 shows a schematic sectional view of an example of an implementation of a light source capable of producing visible light. The light source 200 is provided with a mount lead 202 and an inner lead 204. The mount lead 202 also comprises a reflector cup 206, in which a UV-emitting diode 208 is attached. An n electrode and a p electrode (not shown) of the UV-emitting diode 208 are connected to the mount lead 202 and the inner lead 204, respectively, by separate bonding wires (not shown).

A thin phosphor layer 222 may be applied directly to the surface of the UV-emitting diode 208. The thin phosphor layer 222 may contain a single phosphor or a combination of phosphors that will emit a white light when radiated by UV light from the UV-emitting diode 208. In another implementation, the phosphors may be suspended in an encapsulant material that is spread over the surface of the UV-emitting diode 208. Methods for depositing materials on a semiconductor device, e.g., depositing phosphors on an LED, is described in U.S. Pat. No. 6,864,110 titled “Electrophoretic Processes for the Selective Deposition of Materials on a Semiconducting Device,” issued Mar. 8, 2005, which is incorporated herein, in its entirety, by reference.

Positioned above the thin phosphor layer 222 is a UV reflector 224. In FIG. 2, the UV reflector 224 is shown directly attached to the thin phosphor layer 222 and of substantially the same dimensions. However, the UV reflector may also be positioned directly above and separate from the thin phosphor layer 222 and may also be of different dimensions than the thin phosphor layer 222, e.g., the UV reflector 224 may be wider and overlap the thin phosphor layer 222.

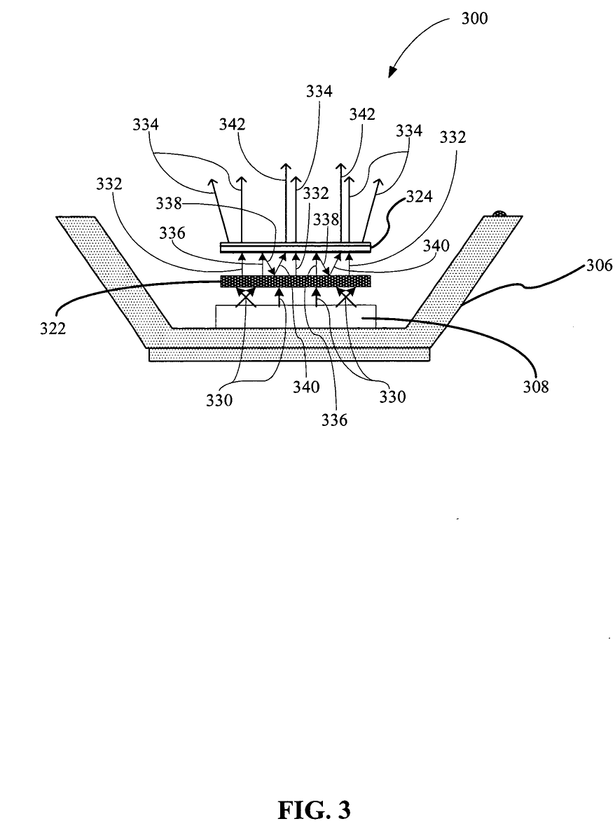

FIG. 3 shows a schematic sectional view of the light source shown in FIG. 2 that shows the UV LED and the UV reflector in greater detail. In FIG. 3, the UV-emitting diode 308 is supported by reflector cup 306 and emits UV light 330 with a wavelength of, for example, from 380 nm to 410 nm. The UV light 330 “excites” the thin phosphor layer 322, and a portion of the UV light 330 is absorbed by the thin phosphor layer 322 and converted to longer wavelength light 332. The longer wavelength light 332 passes through the UV reflector 324 and becomes visible light 334.

A certain portion of UV light 330 will not be converted by the thin phosphor layer 322, resulting in a shorter wavelength light 336 being emitted from the thin phosphor layer 322. The shorter longer wavelength light 336 is reflected by the UV reflector 324, resulting in reflected light 338. The reflected light 338 in turn “excites” the thin phosphor layer 322, resulting in additional longer wavelength light 340. The longer wavelength light 340 passes through the thin phosphor layer 322, resulting in additional visible light 342.

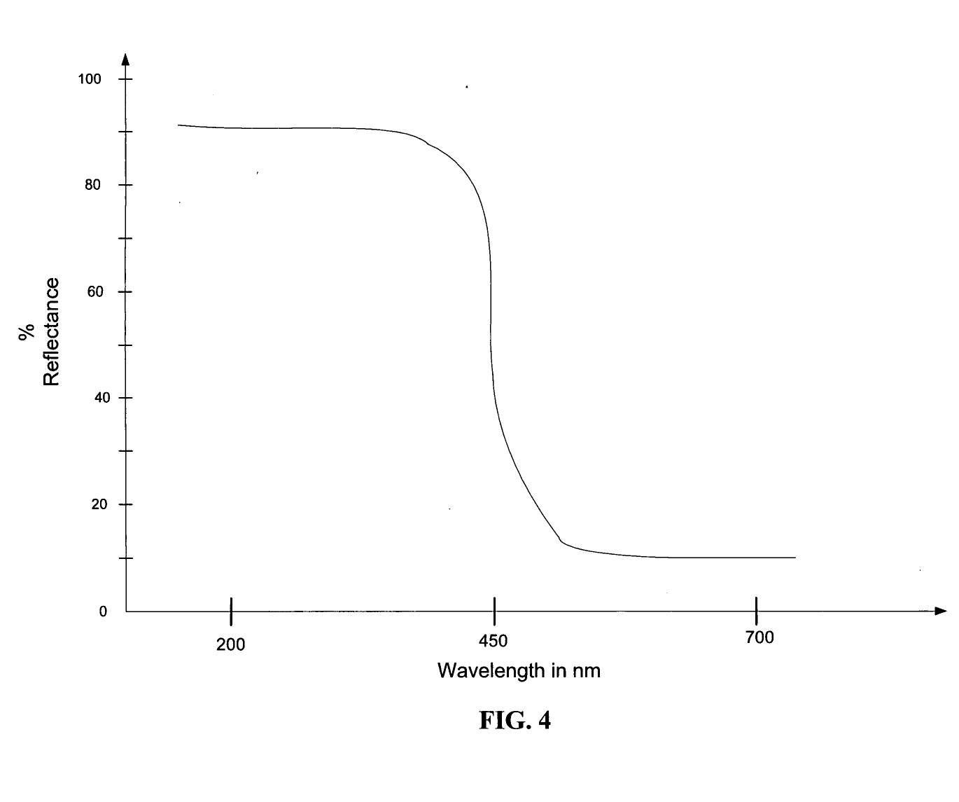

FIG. 4 shows a graphical representation of a plot of reflectivity versus light wavelength in nanometers (“nm”) for an example implementation of the UV reflector shown in FIGS. 2 and 3. FIG. 4 describes an ideal UV reflector that reflects substantially all of the light having a wavelength of about 350 nm or less, while allowing light having a wavelength of about 450 nm or greater to pass.

While the foregoing description refers to the use of a UV LED, the subject matter is not limited to such a device as a radiation source. Any semiconductor radiation source that could benefit from the functionality provided by the components described above may be implemented in the lighting source, including semiconductor laser diodes.

Moreover, it will be understood that the foregoing description of numerous implementations has been presented for purposes of illustration and description. It is not exhaustive and does not limit the claimed inventions to the precise forms disclosed. Modifications and variations are possible in light of the above description or may be acquired from practicing the invention. The claims and their equivalents define the scope of the invention.

What is claimed:

1. A lighting source capable of emitting visible light, the lighting source comprising:
a semiconductor radiation source;
a phosphor layer positioned above the surface of the semiconductor radiation source that emits light when excited with radiation from the semiconductor radiation source that is absorbed by the phosphor layer; and
an ultraviolet (“UV”) reflector configured to reflect that portion of the radiation from the semiconductor radiation source that is not absorbed by the thin phosphor layer back to the thin phosphor layer.

2. The lighting source of claim 1, wherein the semiconductor radiation source is a UV light-emitting diode (“LED”) capable of emitting a UV light.

3. The lighting source of claim 2, wherein the phosphor layer is a thin layer of a phosphor applied directly to the surface of the UV LED.

4. The lighting source of claim 3, wherein the thin phosphor layer contains one or more phosphors that emit visible light when excited by UV light emitted by the UV LED.

5. The lighting source of claim 4, wherein the phosphor layer comprises a single yellow phosphor that emits white light when excited by UV light.

6. The lighting source of claim 4, wherein the phosphor layer comprises a phosphor system selected from the group consisting of garnet-based, silicate-based, oxynitrate-based, nitride-based, sulphide-based, orthosilicate-based, and aluminates and selenide-based phosphor systems.

7. The lighting source of claim 3, wherein the UV reflector is configured to reflect light received from the thin phosphor layer having a wavelength less than a predetermined amount back to the thin phosphor layer, and to allow light with a greater wavelength to pass through the UV reflector.

8. The light source of claim 7, wherein the predetermined amount has a value in a range of about 380 to 410 nanometers (“nm”).

9. The light source of claim 2, wherein the phosphor layer includes a transparent encapsulant in which are suspended one or more phosphors, with the transparent encapsulant being coated upon the surface of the semiconductor radiation source.

10. The light source of claim 9, wherein the transparent encapsulant is a transparent epoxy or silicone system.

11. A method for producing visible light utilizing a semiconductor radiation source and a UV reflector, the method comprising:
emitting light from the semiconductor radiation source;
converting the emitted light to a converted light by exciting a phosphor layer with the emitted light, wherein the converted light has a wavelength that is different from that of the emitted light; and
filtering the converted light through the UV filter.

12. The method of claim 11, wherein the step of filtering the converted light further includes:
reflecting light with a wavelength less than a predetermined length back to the phosphor layer; and
allowing light with a wavelength greater than the predetermined length to pass through the UV filter.

13. The method of claim 12, further including:
converting the emitted light reflected from the UV filter to a secondarily converted light by exciting the phosphor layer with the reflected light, wherein the secondarily converted light has a wavelength that is different from that of the reflected light; and
re-filtering the secondarily converted light through the UV filter.

14. The method of claim 13, wherein the semiconductor radiation source is a UV LED.

15. The method of claim 12, wherein the phosphor layer contains one or more phosphors that emit visible light when excited by UV light emitted by the UV LED.

16. The method of claim 15, wherein the phosphor layer comprises a single yellow phosphor that emits white light when excited by UV light.

17. The method of claim 15, wherein the phosphor layer comprises a phosphor system selected from the group consisting of garnet-based, silicate-based, oxynitrate-based, nitride-based, sulphide-based, orthosilicate-based, and aluminates and selenide-based phosphor systems.

18. The method of claim 12, wherein the predetermined amount has a value in a range of about 380 to 410 nanometers (“nm”).

19. The method of claim 1 1, wherein the phosphor layer includes a transparent encapsulant in which are suspended one or more phosphors, with the transparent encapsulant being coated upon the surface of the semiconductor radiation source.

20. The method of claim 19, wherein the transparent encapsulant is a transparent epoxy or silicone system.
